(19) United States
(12) Patent Application Publication
(10) Pub. No.: US 2025/0298443 A1
(43) Pub. Date: Sep. 25, 2025

(54) DISPLAY DEVICE

(71) Applicant: Samsung Display Co., Ltd., Yongin-si (KR)

(72) Inventor: SUNGSANG AHN, Yongin-si (KR)

(21) Appl. No.: 18/963,047

(22) Filed: Nov. 27, 2024

(30) Foreign Application Priority Data
Mar. 20, 2024 (KR) 10-2024-0038493

(51) Int. Cl. G06F 1/16

(52) U.S. Cl. CPC G06F 1/1656; G06F 1/1624; G06F 1/1652

(57) ABSTRACT

A display device includes a display module having a first region, and a second region extending from the first region in a first direction, a portion of which is folded and disposed under the first region, an extension module disposed between the first region and the second region and disposed under the first region, and a plurality of support bars disposed on a rear surface of the second region. The extension module includes a plurality of fixing plates disposed under the first region, and a guide part having a first part, at least a portion of which is disposed between the plurality of fixing plates under the first region, and a second part, at least a portion of which is disposed between the rear surface of the second region and upper surfaces of the plurality of support bars, wherein centers of the plurality of support bars overlap the second part.

This application claims priority to Korean Patent Application No. 10-2024-0038493, filed on Mar. 20, 2024, and all the benefits accruing therefrom under 35 U.S.C. § 119, the content of which in its entirety is herein incorporated by reference.

### BACKGROUND

### 1. Field

The present invention relates to a display device, and more particularly to a display device with an improved surface quality.

### 2. Description of Related Art

In general, electronic apparatuses, which provide an image to a user, such as smart phones, digital cameras, laptop computers, navigation systems, and smart televisions, include a display device for displaying an image. The display device generates an image and provides the image to a user through a display screen.

Recently, various types of display devices have been developed with technological development of display devices. For example, flexible display devices, which are capable of extending to the outside of a case by sliding or unwinding, have been developed. Flexible display devices capable of being transformed into various shapes may be easy to carry, thereby improving a user's convenience.

### SUMMARY

The present invention provides a display device with an improved surface quality.

An embodiment of the invention provides a display device including a display module having a first region, and a second region which extends from the first region in a first direction, and a portion of which is folded to be disposed under the first region, an extension module disposed between the first region and the second region to be disposed under the first region, and a plurality of support bars disposed on a rear surface of the second region, wherein the extension module includes a plurality of fixing plates disposed under the first region, and a guide part having a first part, at least a portion of which is disposed between the plurality of fixing plates under the first region, and a second part, at least a portion of which is disposed between the rear surface of the second region and the upper surfaces of the plurality of support bars, wherein centers of the plurality of support bars overlap the second part.

In an embodiment, a display device includes a display module having a first region, and a second region which extends from the first region in a first direction, and a portion of which is folded to be disposed under the first region, an extension module disposed between the first region and the second region, and a plurality of support bars, at least some of which are disposed under the second region, and in which a plurality of guide grooves are defined in upper surfaces of the plurality of support bars facing a rear surface of the second region, wherein the extension module includes a guide part which is disposed in the guide groove, and at least a portion of which has a shape of a curved line, and a plurality of fixing plates disposed at two sides of the guide part which are disposed opposite to each other in a second direction crossing the first direction, under the first region, wherein the plurality of support bars move along the guide part.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of a display device in an inserted state, according to an embodiment;

FIG. 1B is a perspective view illustrating an unfolded state of the display device illustrated in FIG. 1A, according to an embodiment;

FIG. 2A is an exploded perspective view of a display device in an inserted state, according to an embodiment;

FIG. 2B is an exploded perspective view of a display device in an unfolded state, according to an embodiment;

FIG. 3 is an exploded, perspective view illustrating a display assembly illustrated in FIG. 2A, according to an embodiment;

FIG. 4 is a cross-sectional view of a display module illustrated in FIG. 3, according to an embodiment;

FIG. 5 is a cross-sectional view of a display panel illustrated in FIG. 4, according to an embodiment;

FIG. 6A is a perspective view illustrating an unfolded state of a lower plate illustrated in FIG. 3, according to an embodiment;

FIG. 6B is a perspective view illustrating one support bar as shown in FIG. 6A, according to an embodiment;

FIG. 7 is an exploded perspective view of a case and an extension module illustrated in FIG. 2A, according to an embodiment;

FIG. 8 is a perspective view of a guide part illustrated in FIG. 7, according to an embodiment;

FIG. 9A is a cross-sectional view of a pressurizing part taken along line I-I′ of FIG. 7, according to an embodiment;

FIG. 9B illustrates coupling of a pressurizing part and a guide part, according to an embodiment;

FIG. 10 is a perspective view illustrating coupling of a rotation part RP and a pressurizing part PP, according to an embodiment;

FIG. 11 is a perspective view illustrating coupling of a guide part and a moving plate, according to an embodiment;

FIG. 12A is a perspective view of a fixing plate illustrated in FIG. 7, according to an embodiment;

FIG. 12B is a perspective view illustrating coupling of a first fixed portion and a fixing plate, and coupling of a second fixed portion and nut parts, according to an embodiment;

FIG. 12C is a perspective view illustrating coupling of a fixing plate and a guide part, according to an embodiment;

FIG. 13A is a perspective view illustrating movement of support bars, according to an embodiment;

FIG. 13B is a perspective view illustrating movement of support bars, according to an embodiment;

FIG. 13C is a perspective view illustrating movement of support bars, according to an embodiment;

FIG. 14A is a cross-sectional view taken along line II-II′ in FIG. 13A, according to an embodiment;

FIG. 14B is a cross-sectional view taken along line IV-VI′ in FIG. 13C, according to an embodiment;

FIG. 15A is a cross-sectional view taken along line III-III′ in FIG. 13A, according to an embodiment; and

FIG. 15B is a cross-sectional view taken along line V-V′in FIG. 13C, according to an embodiment.

### DETAILED DESCRIPTION

In this specification, it will be understood that when an element (or region, layer, portion, etc.) is referred to as being “on”, “connected to” or “coupled to” another element or layer, the element can be directly disposed on/connected to/coupled to the other element or intervening elements may be present.

Like reference numerals or symbols refer to like elements throughout the specification. In addition, in terms of drawings, the thickness and the ratio and the dimension of the element are exaggerated for effective description of the technical contents. As used herein, the term “and/or” includes any and all combinations of one or more of the associated listed items.

Terms such as first and second may be used to describe various components, but the components should not be limited by the terms. These terms are only used for the purpose of distinguishing one component from other components. For example, without departing from the scope of the invention, a first component may be referred to as a second component, and similarly, a second component may be referred to as a first component. Singular expressions include plural expressions unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the accompanying drawings.

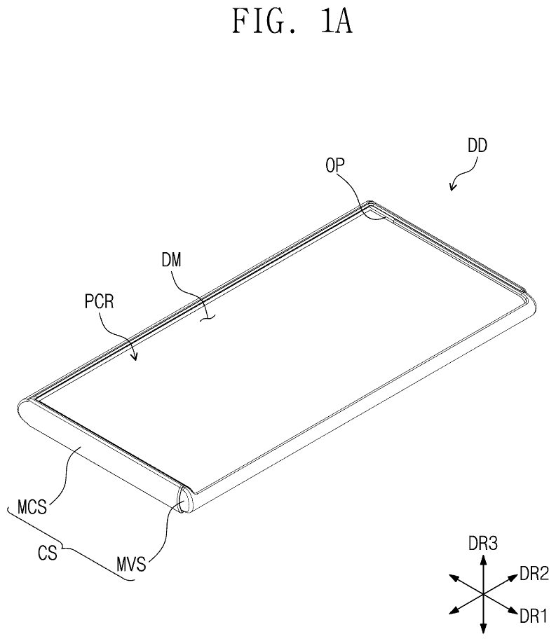

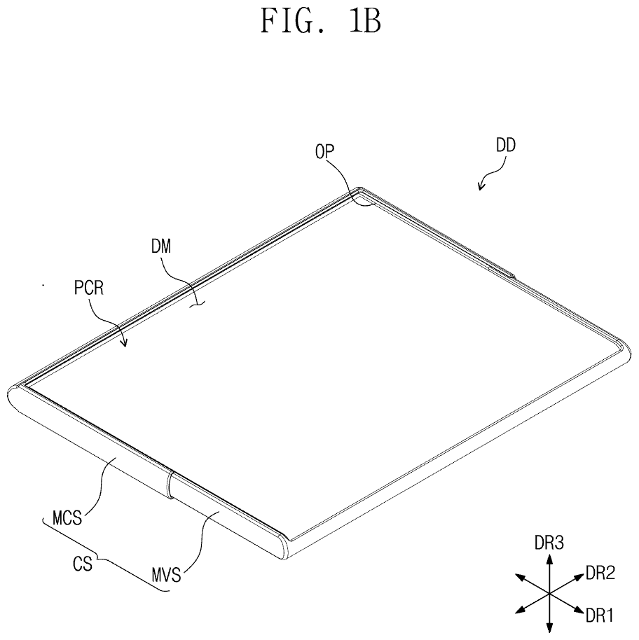

FIG. 1A is a perspective view of a display device in an inserted state, according to an embodiment. FIG. 1B is a perspective view illustrating an unfolded state of the display device illustrated in FIG. 1A, according to an embodiment.

In an embodiment and referring to FIG. 1A, a display device DD may include a display assembly PCR, and a case CS which accommodates the display assembly PCR. The display assembly PCR may include a display module DM, where the display module DM may be exposed to the outside through an opening OP which is defined in an upper part of the case CS.

The case CS may include a main case MCS and a moving case MVS, where the main case MCS and the moving case MVS may be coupled to each other to accommodate the display assembly PCR. The moving case MVS may be coupled to the main case MCS so as to move in a first direction DR1.

Hereinafter, a direction crossing the first direction DR1 may be defined as a second direction DR2. A direction substantially perpendicularly crossing a plane defined by the first and second directions DR1 and DR2 may be defined as a third direction DR3. In this specification, the wording “when viewed on plane” may mean “a state viewed from the third direction DR3.”

As illustrated in FIG. 1A, an area of a display surface of the display assembly PCR that is exposed to the outside in a state in which the moving case MVS is closest to the main case MCS may be set to a minimum area. This state of the display device DD may be defined as an inserted state.

In an embodiment, an area of the display module DM that is exposed to the outside of the case CS may be adjustable depending on a movement of the moving case MVS. For example, the moving case MVS may move in the first direction DR1 due to an external force applied by a user. As illustrated in FIG. 1B, an area of the display module DM exposed to the outside may increase according to the movement of the moving case MVS, and a user may view an image through a larger screen.

In an embodiment and as illustrated in FIG. 1B, a state of the display device DD in which an area of the display assembly PCR exposed to the outside becomes greater than that in the inserted state in FIG. 1A may be defined as an unfolded state.

Although not illustrated, in an inserted mode, a portion of the display module DM which is not exposed to the outside, except the exposed portion of the display module DM through the opening OP, may be disposed inside the case CS.

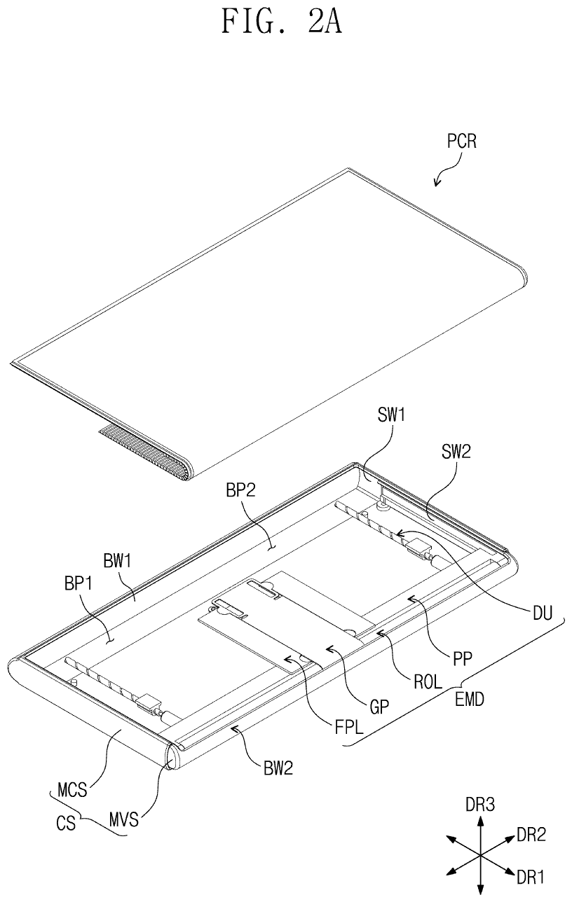

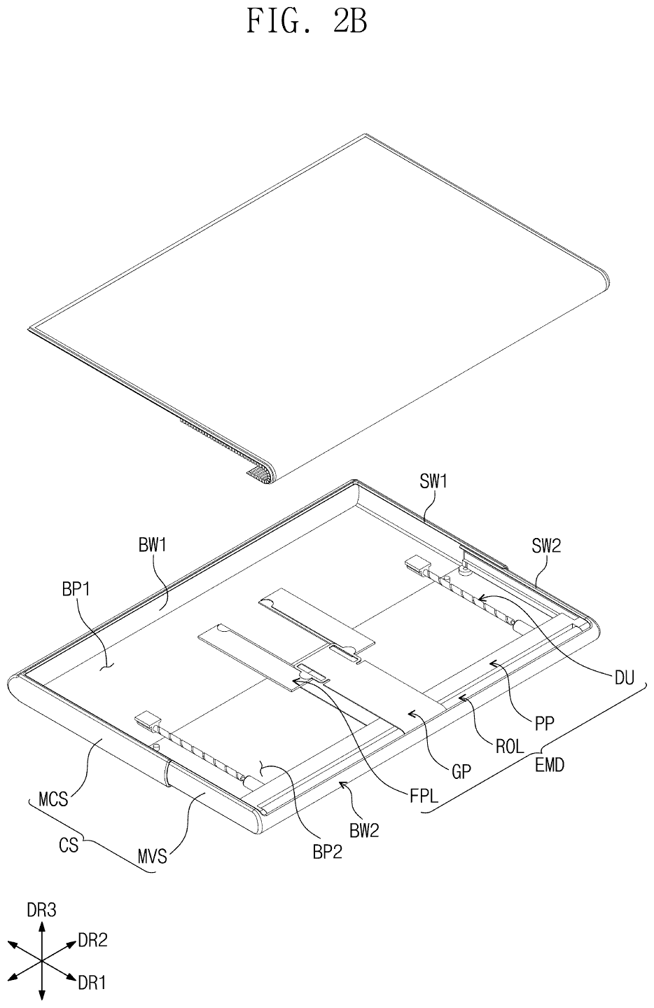

FIGS. 2A and 2B are exploded perspective views of a display device, according to an embodiment.

By way of example, FIG. 2A illustrates a display assembly PCR, a case CS, and an extension module EMD in an inserted state, according to an embodiment, and FIG. 2B illustrates the display assembly PCR, the case CS, and the extension module EMD in an unfolded state, according to an embodiment.

In an embodiment and referring to FIGS. 2A and 2B, a main case MCS may include a first bottom part BP1, a plurality of first sidewall parts SW1, and a first partition wall BW1. The first bottom part BPI may be directed parallel to a plane defined by a first direction DR1 and a second direction DR2.

The first sidewall parts SW1 may extend in a third direction DR3 from two sides of the first bottom part BP1 which are disposed opposite to each other in the second direction DR2. The first sidewall parts SW1 may each have a flat surface defined by the first direction DR1 and the third direction DR3, and may extend longer in the first direction DR1 than in the third direction DR3. The first sidewall parts SW1, which face each other, may be symmetrical to each other in the second direction DR2.

The first partition wall BW1 may extend in the third direction DR3 from one side among two sides of the main case MCS which are disposed opposite to each other in the first direction DR1. The first partition wall BW1 may be disposed between the first sidewall parts SW1. The first partition wall BW1 may have a flat surface defined by the second direction DR2 and the third direction DR3, and may extend longer in the second direction DR2 than in the third direction DR3. One side among the two sides of the main case MCS which are opposite to each other in the first direction DR1 may be defined as a side disposed far away from the moving case MVS.

In an embodiment, the moving case MVS may include a second bottom part BP2, a plurality of second sidewall parts SW2, and a second partition wall BW2. The second bottom part BP2 may have a flat surface defined by the first direction DR1 and the second direction DR2. The second bottom part BP2 may be disposed on the first bottom part BP1.

The second sidewall parts SW2 may extend in the third direction DR3 from two sides of the second bottom parts BP2 which are disposed opposite to each other in the second direction DR2. The second sidewall parts SW2 may each have a flat surface defined by the first direction DR1 and the third direction DR3, and may extend longer in the first direction DR1 than in the third direction DR3. The second sidewall parts SW2, which face each other, may be symmetrical to each other in the second direction DR2.

The second sidewall parts SW2 may be disposed between the first sidewall parts SW1 facing each other. The second sidewall parts SW2 may move in the first direction DR1 along inner surfaces of the first sidewall parts SW1 facing each other.

The second partition wall BW2 may extend in the third direction DR3 from one side among two sides of the moving case MVS which are disposed opposite to each other in the first direction DR1. The second partition wall BW2 may be disposed between the second sidewall parts SW2. The second partition wall BW2 may extend longer in the second direction DR2 than in the third direction DR3. One side among the two sides of the moving case MVS which are disposed opposite to each other in the first direction DR1 may be defined as a side disposed far away from the main case MCS.

In an embodiment, the display device DD may include the extension module EMD, where the extension module EMD may be accommodated inside the case CS. The extension module EMD may be coupled to the case CS, and may be unfolded or folded in the first direction DR1. The extension module EMD may include drive parts DU, a pressurizing part PP, a roller ROL, a guide part GP, and a plurality of fixing plates FPL. The extension module EMD will be described in detail later.

In an embodiment, when the extension module EMD is unfolded, the moving case MVS connected to the extension module EMD may move in the first direction DR1. When the moving case MVS moves in the first direction DR1, an area of the second bottom part BP2 overlapping the first bottom part BP1 may be variable. In an unfolded state, the area of the second bottom part BP2 overlapping the first bottom part BP1 may be a minimum area. In an inserted state, the area of the second bottom part BP2 overlapping the first bottom part BP1 may be a maximum area.

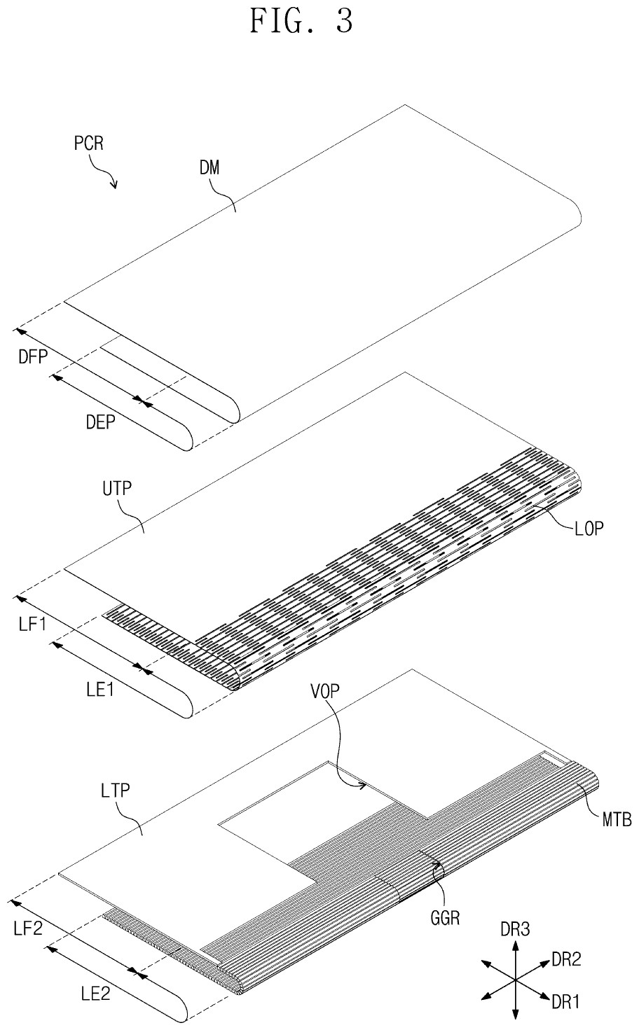

FIG. 3 is a perspective view illustrating a display assembly illustrated in FIG. 2A, according to an embodiment.

By way of example, FIG. 3 illustrates a display assembly PCR when the display device DD (see FIG. 1A) is in an inserted state.

In an embodiment and referring to FIG. 3, the display assembly PCR may include a display module DM, an upper plate UTP, and a lower plate LTP. The display module DM may include a first region DFP and a second region DEP extending from the first region DFP in a first direction DR1.

The first region DFP may be exposed to the outside of the case CS in FIG. 2A regardless of whether the display device is in an inserted state in FIG. 1A or in an unfolded state in FIG. 1B. The first region DFP may be directed parallel to a plane defined by the first direction DR1 and a second direction DR2.

The second region DEP may extend from the first region DFP in the first direction DR1, and may be folded such that a portion thereof is disposed under the first region DFP. An area of the second region DEP exposed to the outside of the case CS may vary depending on whether the display device DD (see FIG. 1A) is in an inserted state or in an unfolded state.

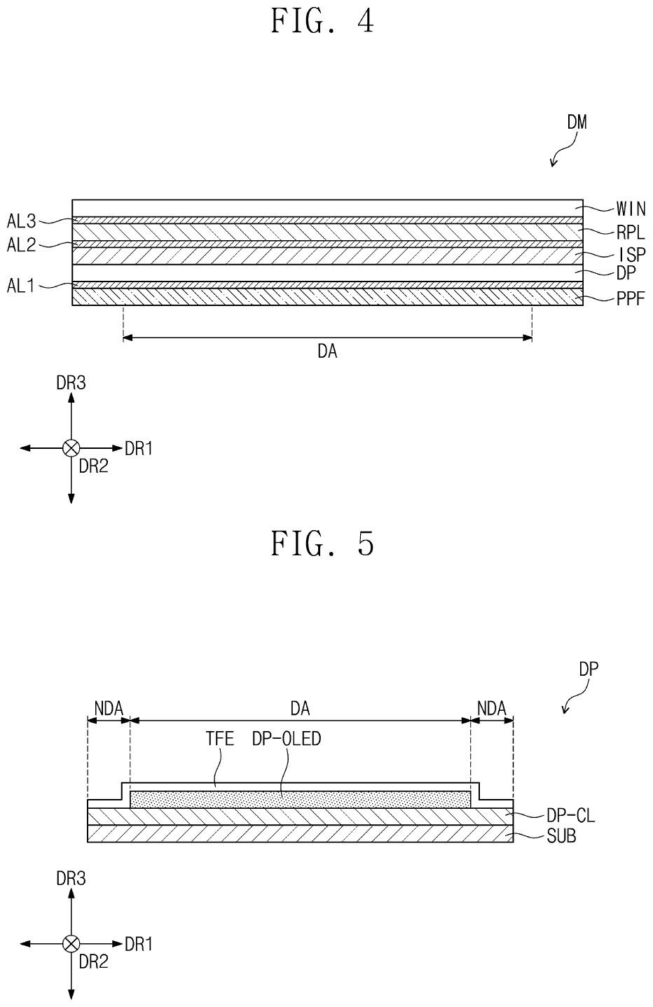

FIG. 4 is a cross-sectional view of a display module illustrated in FIG. 3, according to an embodiment. FIG. 5 is a cross-sectional view of a display panel illustrated in FIG. 4, according to an embodiment.

In an embodiment and referring to FIG. 4, a display module DM may include a display panel DP, an input sensing part ISP, an anti-reflection layer RPL, a window WIN, and a panel protection film PPF.

The display panel DP may be a flexible display panel. The display panel DP, according to an embodiment, may be a light-emitting display panel, and is not particularly limited. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and the like. Hereinafter, the display panel DP will be described as the organic light-emitting display panel.

In an embodiment, the input sensing part ISP may be disposed on the display panel DP, where the input sensing part ISP may include a plurality of sensing parts (not illustrated) for sensing an external input in a capacitive manner. The input sensing part ISP may be manufactured directly on the display panel DP during the manufacture of the display device DD. However, the invention is not limited thereto, and, in another embodiment, the input sensing part ISP may be manufactured as a separate panel from the display panel DP, and attached to the display panel DP by an adhesive layer.

In an embodiment, the anti-reflection layer RPL may be disposed on the input sensing part ISP, where the anti-reflection layer RPL may be defined as a film for preventing reflection of external light. The anti-reflection layer RPL may reduce reflectance for external light which is incident from above the display device DD toward the display panel DP.

When the external light propagating toward the display panel DP is reflected from the display panel DP and again provided to a user outside the display panel DP, the user may view the external light, as if the display panel is a mirror. In an embodiment and to prevent such a phenomenon, the anti-reflection layer RPL may include a plurality of color filters for displaying colors which are the same as those of pixels of the display panel DP.

In an embodiment, the color filters may filter external light into the same colors as those of the pixels. In such cases, the external light may be invisible to a user. However, the invention is not limited thereto, and in another embodiment, the anti-reflection layer RPL may include a phase retarder and/or a polarizer so as to reduce external light reflectance.

In an embodiment, the window WIN may be disposed on the anti-reflection layer RPL, where the window WIN may protect the display panel DP, the input sensing part ISP, and the anti-reflection layer RPL from an external impact and a scratch.

In an embodiment, the panel protection film PPF may be disposed under the display panel DP, where the panel protection film PPF may protect a lower part of the display panel DP. The panel protection film PPF may include a flexible plastic substance such as polyethylene terephthalate (PET).

In an embodiment and referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

In an embodiment, the substrate SUB may include a display region DA and a non-display region NDA disposed adjacent to the display region DA. The substrate SUB may include a flexible plastic substance such as polyimide (PI). The display element layer DP-OLED may be disposed on the display region DA.

In an embodiment, a plurality of pixels may be disposed in the circuit element layer DP-CL and the display element layer DP-OLED. The pixels may each include transistors which are disposed on the circuit element layer DP-CL, and a light-emitting element which is disposed on the display element layer DP-OLED and which is connected to the transistors. A configuration of the pixel will be described in detail below.

In an embodiment, the thin-film encapsulation layer TFE may be disposed on the circuit element layer DP-CL so as to cover the display element layer DP-OLED. The thin-film encapsulation layer TFE may protect the pixels from moisture, oxygen, and external foreign matters.

In an embodiment and referring again to FIG. 3, the upper plate UTP may be disposed on a lower surface of the display module DM. The upper plate UTP may include a metal substance such as stainless steel (for example, SUS 316), but the metal substance of the upper plate UTP is not limited thereto. In addition, the invention is not limited thereto, and, in another embodiment, the upper plate UTP may include a non-metal substance such as plastic.

The upper plate UTP may include a first fixed portion LF1 and a first extension portion LE1. The first fixed portion LF1 may be directed parallel to a plane defined by the first direction DR1 and the second direction DR2, where the first fixed portion LF1 may overlap the first region DFP.

The first extension portion LE1 and the first fixed portion LF1 may be arranged in the first direction DR1. The first extension portion LE1 may extend in the first direction DR1 from the first fixed portion LF1, and a portion thereof may be disposed under the first fixed portion LF1. The first extension portion LE1 may overlap the second region DEP.

In an embodiment, a plurality of openings LOP may be defined in the first extension portion LE1, where the openings LOP may overlap the second region DEP. Since the openings LOP are defined, the rigidity of the first extension portion LE1 may decrease, and the flexibility thereof may increase. Thus, the first extension portion LE1 may be easily bent.

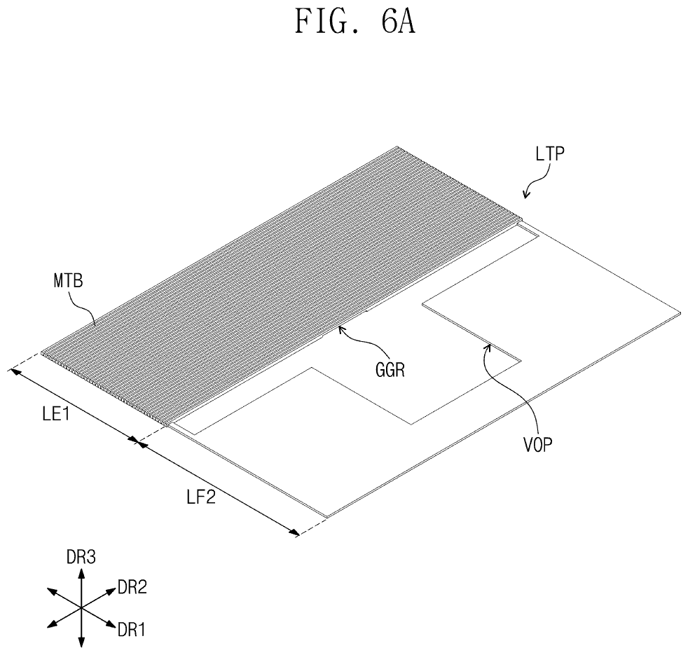

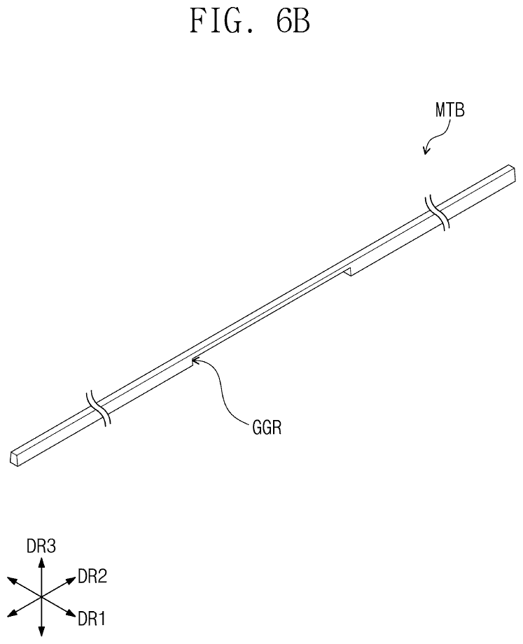

FIG. 6A is a perspective view illustrating an unfolded state of the lower plate illustrated in FIG. 3, according to an embodiment. FIG. 6B is a perspective view illustrating one support bar illustrated in FIG. 6A, according to an embodiment.

By way of example, FIG. 6A illustrates that a lower surface of a second fixed portion LF2 and lower surfaces of support bars MTB face upwards, according to an embodiment, and FIG. 6B illustrates that an upper surface, facing the first extension portion LE1, of a support bar MTB faces downwards, according to an embodiment.

In an embodiment and referring to FIGS. 3 and 6A, the lower plate LTP may be disposed under the upper plate UTP. For example, the lower plate LTP may be coupled to a lower surface of the upper plate UTP through welding. However, the invention is not limited thereto, and, in another embodiment, the lower plate LTP may be coupled thereto through various methods.

In an embodiment, the lower plate LTP may include the second fixed portion LF2 and a second extension portion LE2 arranged along with the second fixed portion LF2 in the first direction DR1. The second fixed portion LF2 may be directed parallel to a plane defined by the first direction DR1 and the second direction DR2, where the second fixed portion LF2 may overlap the first fixed portion LF1 and the first region DFP.

In an embodiment, a receiving opening VOP may be defined in the second fixed portion LF2, where the receiving opening VOP may be defined by extending from one side, among two sides of the second fixed portion LF2 which are disposed opposite to each other in the first direction DR1, toward the other side in the first direction DR1. The one side among the two sides of the second fixed portion LF2 which are disposed opposite to each other in the first direction DR1 may be defined as a side facing the support bars MTB which will be described later.

In an embodiment, the second extension portion LE2 may include the plurality of support bars MTB. When the lower plate LTP is unfolded, the support bars MTB may extend in the second direction DR2, and may be arranged in the first direction DR1. When the support bars MTB are accommodated inside the case CS (see FIG. 2A), some of the support bars MTB may be arranged in a curved line form.

In an embodiment, the second extension portion LE2 may overlap the second region DEP and the first extension portion LE1. Upper surfaces of the support bars MTB may face a rear surface of the second region DEP and may be attached to a rear surface of the first extension portion LE1.

In an embodiment, guide grooves GGR may be defined on the upper surfaces of the support bars MTB. Hereinafter, for convenience of explanation, one support bar MTB among the plurality of support bars MTB will be described with reference to FIG. 6B. The guide groove GGR may be defined in a center of the support bar MTB. Distances to the guide groove GGR from both ends of the guide groove GGR, which are disposed opposite to each other in the second direction DR2, may be the same.

The guide groove GGR may extend from the upper surface of the support bar MTB toward a lower surface thereof in a third direction DR3. For example, in FIG. 6B, the depth of the guide groove GGR may be the same as the half of the thickness of the support bar MTB, but the depth of the guide groove GGR is not limited thereto. In addition, the guide groove GGR may have a shape corresponding to a portion of a quadrangular shape, but the shape of the guide groove GGR is not limited thereto. In an embodiment, one guide groove GGR is defined in one support bar MTB, but the number of the guide grooves GGR defined in one support bar MTB is not limited thereto and may be the plural number.

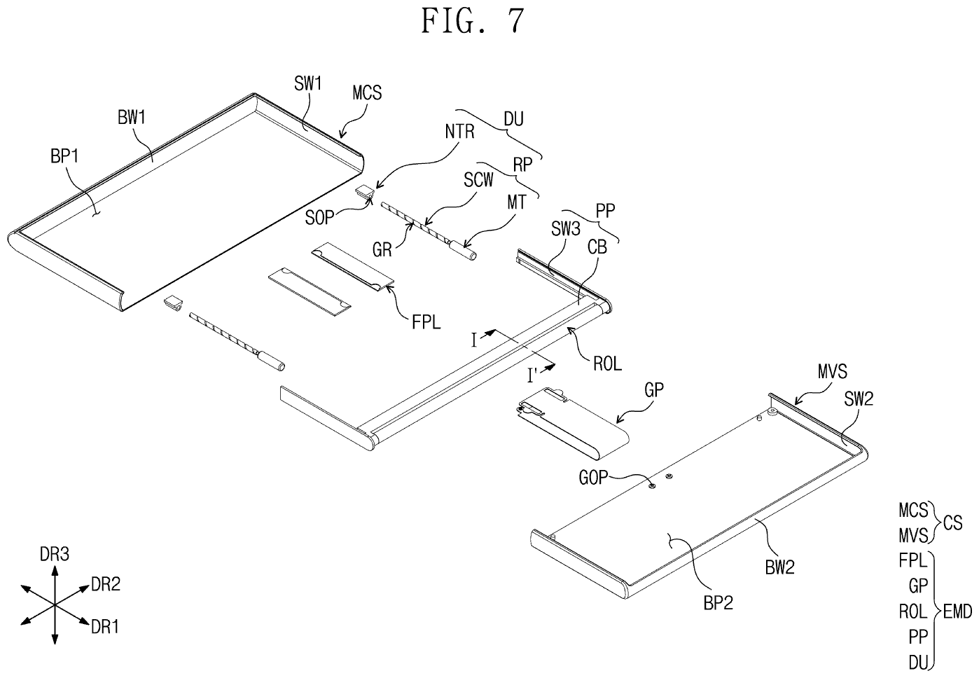

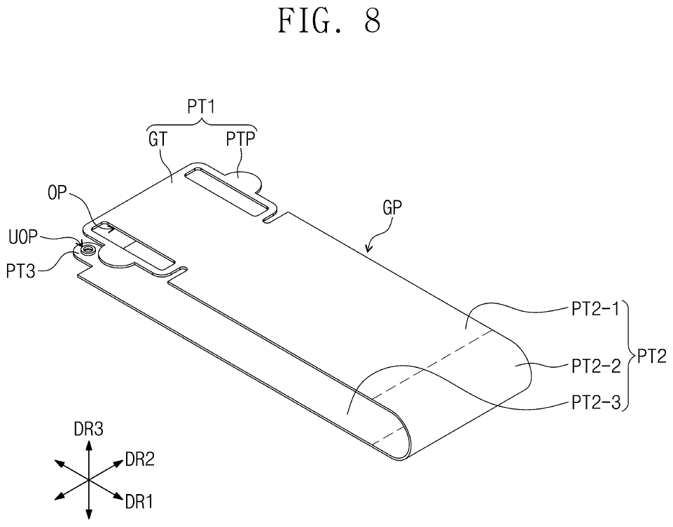

FIG. 7 is an exploded perspective view of a case and an extension module as illustrated in FIG. 2A, according to an embodiment. FIG. 8 is a perspective view of a guide part illustrated in FIG. 7, according to an embodiment.

Among components illustrated in FIGS. 7 and 8, description of components which are the same as/similar to the components described with reference to the aforementioned drawings will be omitted or simplified.

In an embodiment and referring to FIGS. 7 and 8, an extension module EMD may include drive parts DU, a pressurizing part PP, a roller ROL, a guide part GP, and a plurality of fixing plates FPL.

In an embodiment, a portion of the guide part GP may be bent with respect to an axis that is directed parallel to a second direction DR2 so as to make a curved shape. The guide part GP may include a first part PT1, a second part PT2, and a third part PT3. In an embodiment, the first part PT1, the second part PT2, and the third part PT3 may be formed integrally.

In an embodiment, the first part PT1 may include a moving portion GT and a plurality of protrusion portions PTP extending from the moving portion GT. The moving portion GT may be directed parallel to a plane defined by a first direction DR1 and a second direction DR2. For example, the moving portion GT may have a plurality of short sides extending in the first direction DR1, and a plurality of long sides extending in the second direction DR2.

In an embodiment, a plurality of openings OP may be defined adjacent to two sides of the moving portion GT which are disposed opposite to each other in the second direction DR2. For example, the openings OP may each have a shape corresponding to a quadrangular shape, but the shape of the openings OP is not limited thereto. Since the openings OP are defined, the rigidity of edges of the two sides of the moving portion GT, which are disposed opposite to each other in the second direction DR2, may be reduced.

In an embodiment, the protrusion portions PTP may extend in the second direction DR2 from the two sides of the moving portion GT which are disposed opposite to each other in the second direction DR2. In an embodiment, the moving portion GT and the protrusion portions PTP may be formed integrally. For example, the protrusion portions PTP may each have a semicircular shape, but the shape of the protrusion portions PTP is not limited thereto.

In an embodiment, the second part PT2 may extend in the first direction DR1 from the first part PT1, and a portion of the second part PT2 may be bent to be disposed under the first part PT1. The second part PT2 may include a (2-1)-th part PT2-1, a (2-2)-th part PT2-2, and a (2-3)-th part PT2-3.

The (2-1)-th part PT2-1 may extend in the first direction DR1 from the first part PT1. The (2-1)-th part PT2-1 may be directed parallel to a plane defined by the first direction DR1 and the second direction DR2. The (2-1)-th part PT2-1 may be disposed on the same plane as the first part PT1. A width of the (2-1)-th part PT2-1 in the second direction DR2 may be the same as a width of the first part PT1 in the first direction DR1.

The (2-2)-th part PT2-2 may extend from the (2-1)-th part PT2-1 and may be bent with respect to an axis that is directed parallel to the second direction DR2. When viewed in the second direction DR2, the (2-2)-th part PT2-2 may have a curved shape.

The (2-3)-th part PT2-3 may extend in a direction opposite to the first direction DR1 from the (2-2)-th part PT2-2. The (2-3)-th part PT2-3 may be disposed under the (2-1)-th part PT2-1. The (2-3)-th part PT2-3 may be directed parallel to the (2-1)-th part PT2-1.

The third part PT3 may extend in the direction opposite to the first direction DR1 from the (2-3)-th part PT2-3. For example, the third part PT3 may have a semicircular shape. A coupling opening UOP may be defined in a center of the third part PT3.

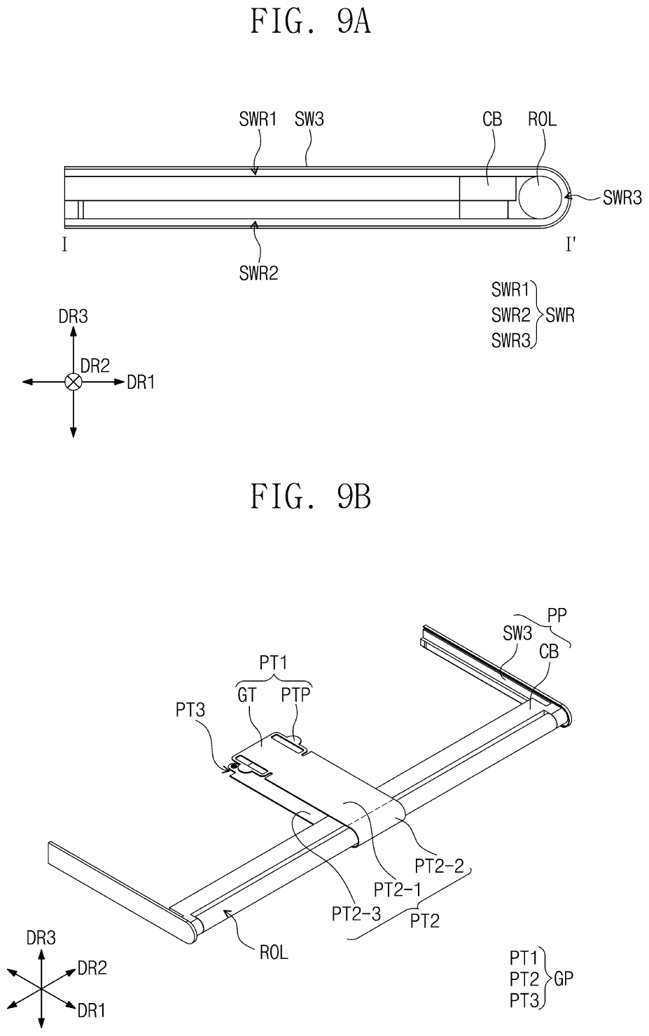

FIG. 9A is a cross-sectional view of a pressurizing part taken along line I-I′ of FIG. 7, according to an embodiment. FIG. 9B illustrates coupling of a pressurizing part and a guide part, according to an embodiment.

Among components illustrated in FIGS. 9A and 9B, description of components which are the same as/similar to the components described with reference to the aforementioned drawings will be omitted or simplified.

In an embodiment and referring to FIG. 7, the pressurizing part PP may include a rod part CB and a plurality of third sidewall parts SW3 coupled to the rod part CB. The rod part CB may extend in the second direction DR2.

The third sidewall parts SW3 may be coupled to two sides of the rod part CB which are disposed opposite to each other in the second direction DR2. The third sidewall parts SW3 may face each other in the second direction DR2. The third sidewall parts SW3 may each have a flat surface defined by the first direction DR1 and a third direction DR3. The third sidewall parts SW3 may extend longer in the second direction DR2 than in the third direction DR3. The third sidewall parts SW3 may respectively have shapes corresponding to the second sidewall parts SW2 of the moving case MVS.

In an embodiment and referring to FIGS. 7 and 9A, sliding grooves SWR may be defined in mutually facing inner surfaces of the third sidewall parts SW3. Hereinafter, for convenience of explanation, an inner surface of one third-sidewall-part SW3 among the third sidewall parts SW3 will be described.

In an embodiment, the sliding grooves SWR may include a first sliding groove SWR1, a second sliding groove SWR2, and a third sliding groove SWR3. The first sliding groove SWR1 may be defined to be adjacent to an upper portion of the third sidewall part SW3 and may extend in the first direction DR1.

In an embodiment, the second sliding groove SWR2 may be defined to be adjacent to a lower portion of the third sidewall part SW3 and may be defined under the first sliding groove SWR1. The second sliding groove SWR2 may extend in the first direction DR1. The first sliding groove SWR1 and the second sliding groove SWR2 may be symmetrical to each other in the third direction DR3.

In an embodiment, the third sliding groove SWR3 may connect the first sliding groove SWR1 and the second sliding groove SWR2. The third sliding groove SWR3 may be defined as a curved shape.

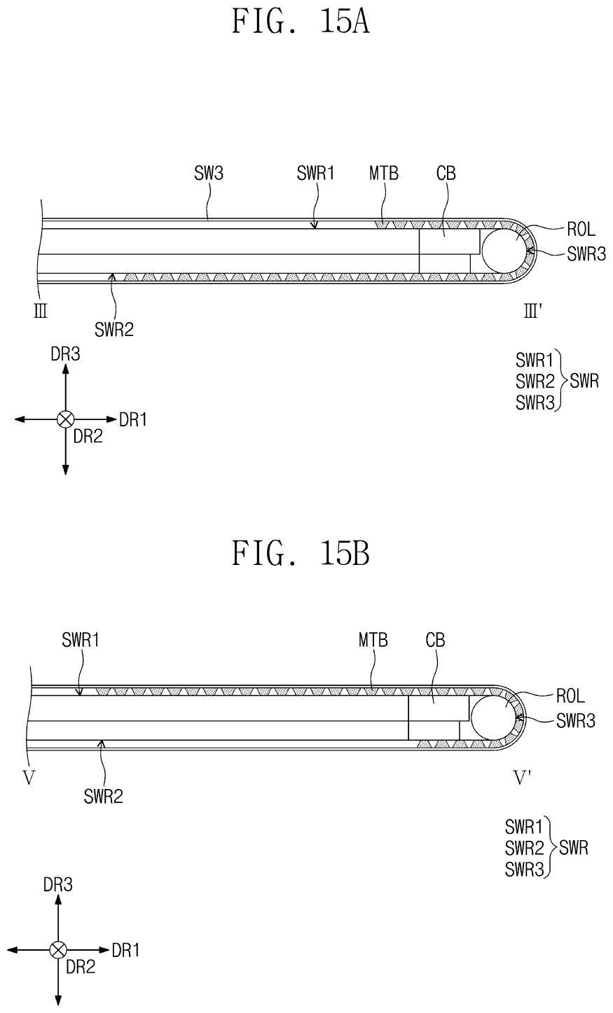

In an embodiment, the two sides, which are disposed opposite to each other in the second direction DR2, of the support bars MTB illustrated in FIG. 3 may be disposed in the sliding grooves SWR. When the display device DD (see FIG. 1A) changes into an unfolded state or into an inserted state, the support bars MTB may move along the sliding groove SWR. The support bars MTB which move along the sliding groove SWR will be described in detail with reference to FIGS. 15A and 15B.

By way of example, an embodiment in which the sliding groove SWR is defined in the inner surface of the third sidewall part SW3 is explained. However, in another embodiment, the sliding groove SWR of the third sidewall part SW3 may be omitted.

In an embodiment and referring to FIG. 7, the roller ROL may have a cylindrical shape extending in the second direction DR2. The roller ROL may be coupled to the pressurizing part PP. The roller ROL may be coupled to the rod part CB. The roller ROL may be disposed between the third sidewall parts SW3. The roller ROL may be coupled to the rod part CB, and may rotate about a rotation axis that is directed parallel to the second direction DR2.

In an embodiment and referring to FIG. 9B, the pressurizing part PP and the roller ROL may be disposed between the (2-1)-th part PT2-1 and the (2-3)-th part PT2-3. The rod part CB and the roller ROL may be disposed between the (2-1)-th part PT2-1 and the (2-3)-th part PT2-3. The (2-2)-th part PT2-2 may surround an outer surface of the roller ROL.

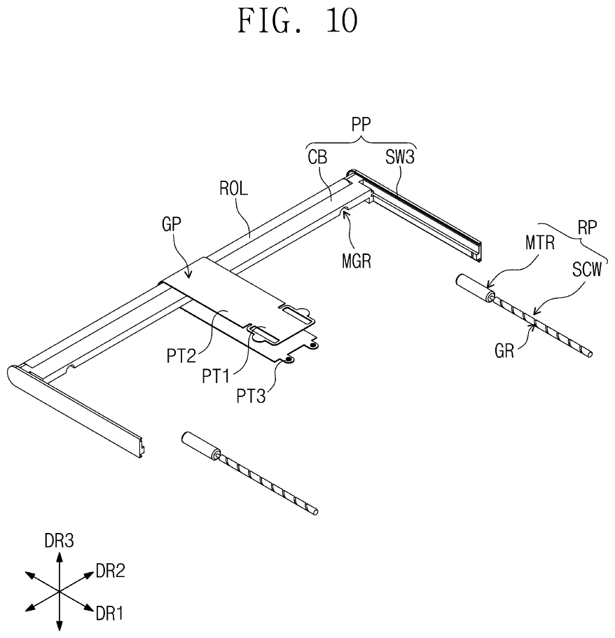

FIG. 10 is a perspective view illustrating coupling of a rotation part and a pressurizing part PP, according to an embodiment.

Among components illustrated in FIG. 10, description of components which are the same as/similar to the components described with reference to the aforementioned drawings will be omitted or simplified.

In an embodiment and referring to FIGS. 7 and 10, the plurality of drive parts DU may be arranged to be spaced apart from each other in the second direction DR2. For example, two drive parts DU are illustrated in FIG. 7, but the number of the drive parts DU is not limited thereto.

In an embodiment, the drive parts DU may include rotation parts RP and nut parts NTR. The rotation parts RP may include screw parts SCW and motor parts MTR. The screw parts SCW may each have a rod shape extending in the first direction DR1. Spiral grooves GR may be defined in outer surfaces of the screw parts SCW.

In an embodiment, the motor parts MTR may be respectively coupled to one-end portions, which face the pressurizing part PP, of the screw parts SCW. The motor parts MTR may each have a cylindrical shape. The motor parts MTR may rotate about a rotation axis that is directed parallel to the first direction DR1 via an external power supply. When the motor parts MTR rotate about the rotation axis that is directed parallel to the first direction DR1, the screw parts SCW coupled to the motor parts MTR may rotate about the rotation axis that is directed parallel to the first direction DR1.

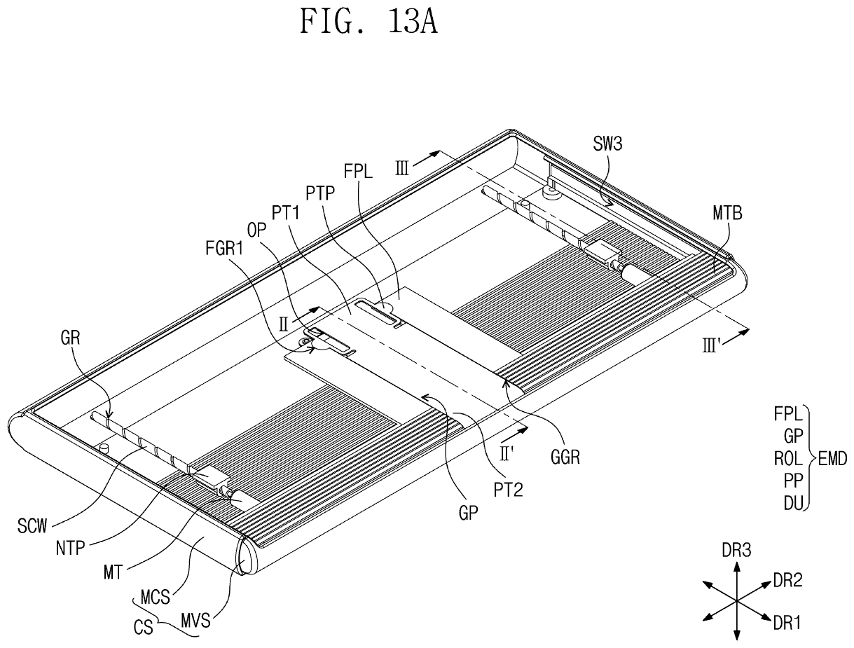

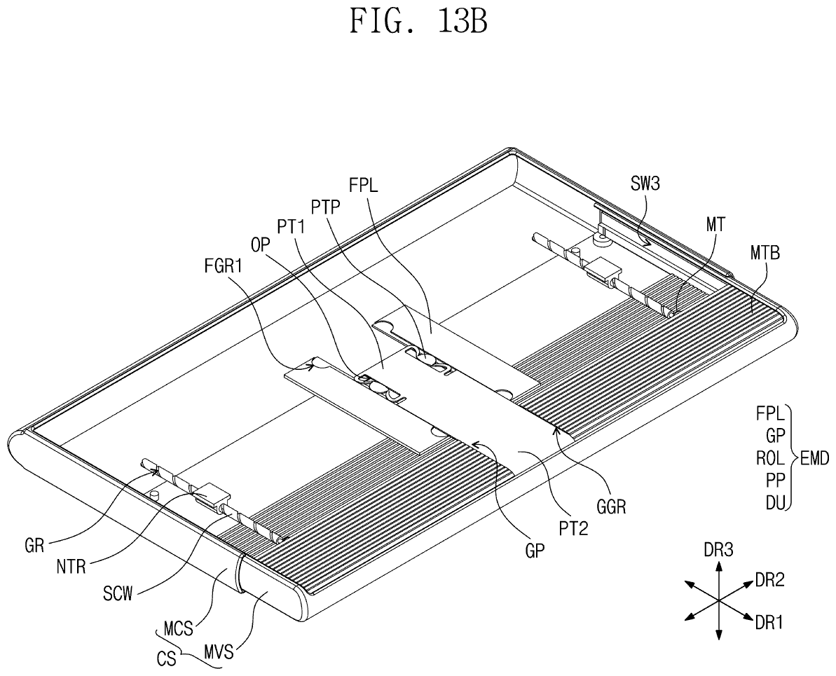

In an embodiment, the screw parts SCW may be inserted into openings SOP defined in the nut parts NTR. Although not illustrated, projections corresponding to the spiral grooves GR may be disposed inside the openings SOP. Accordingly, when the screw parts SCW rotate about the rotation axis that is directed parallel to the first direction DR1, the spiral grooves GR and the projections may interlock with each other. Accordingly, the screw parts SCW may reciprocate in the first direction DR1. The movement of the screw parts SCW will be described in detail with reference to FIGS. 13A to 13C.

In an embodiment, drive grooves MGR may be defined at one side of the rod part CB facing the rotation parts RP. The drive grooves MGR may be arranged in the second direction DR2. The drive grooves MGR may have shapes corresponding to those of the motor parts MTR. For example, the drive grooves MGR may each have a shape corresponding to a portion of a circle. The rotation parts RP may be coupled to the rod part CB. Each of the rotation parts RP may be inserted into and coupled to a corresponding drive groove MGR among the drive grooves MGR.

In an embodiment, the third part PT3 may be provided in plurality, and the plurality of third parts PT3 may extend from the (2-3)-th part PT2-3 and may be arranged in the second direction DR2.

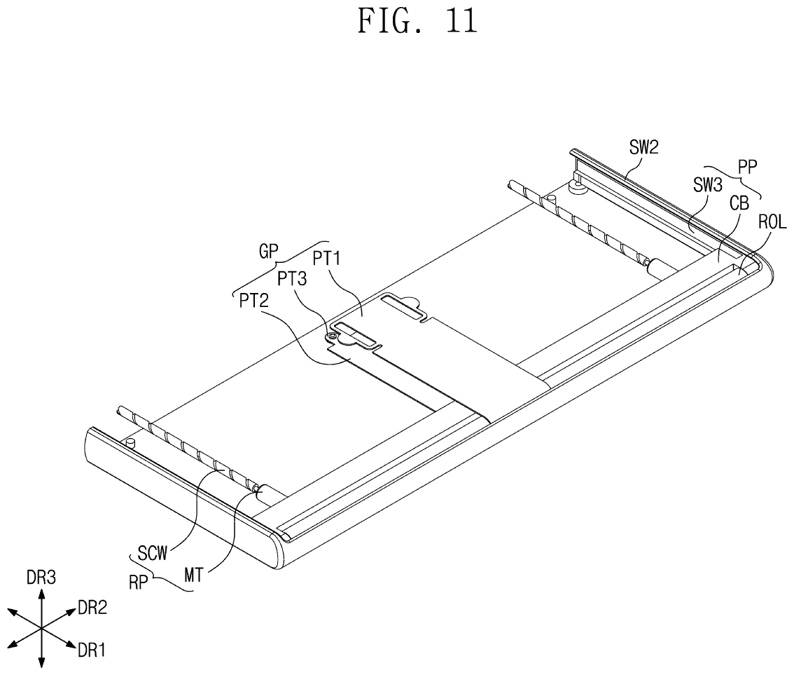

FIG. 11 is a perspective view illustrating coupling of a guide part and a moving plate, according to an embodiment.

Among components illustrated in FIG. 11, description of components which are the same as/similar to the components described with reference to the aforementioned drawings will be omitted or simplified.

In an embodiment and referring to FIGS. 7 and 11, a plurality of fixing openings GOP may be defined in the second bottom part BP2. The fixing openings GOP may be defined to be disposed adjacent to one side, facing the main case MCS, among the two sides of the second bottom part BP2 which are disposed opposite to each other in the first direction DR1. The fixing openings GOP may be arranged in the second direction DR2.

In an embodiment, the guide part GP, the pressurizing part PP, and the roller ROL may be accommodated in the moving case MVS. The guide part GP may be disposed on the second bottom part BP2. The third part PT3 of the guide part GP may overlap the fixing openings GOP. Although not illustrated, fastening screws may pass through the third part PT3 and may be coupled to the fixing openings GOP. Accordingly, the guide part GP may be fixed to the moving case MVS.

In an embodiment, the third sidewall parts SW3 of the pressurizing part PP may be disposed between the inner surfaces of the second sidewall parts SW2 that are facing each other. The third sidewall parts SW3 may be coupled to the second sidewall parts SW2. Accordingly, the pressurizing part PP may be fixed to the moving case MVS.

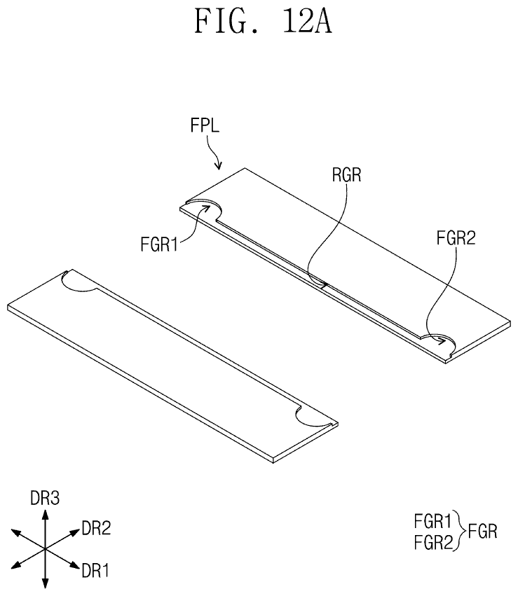

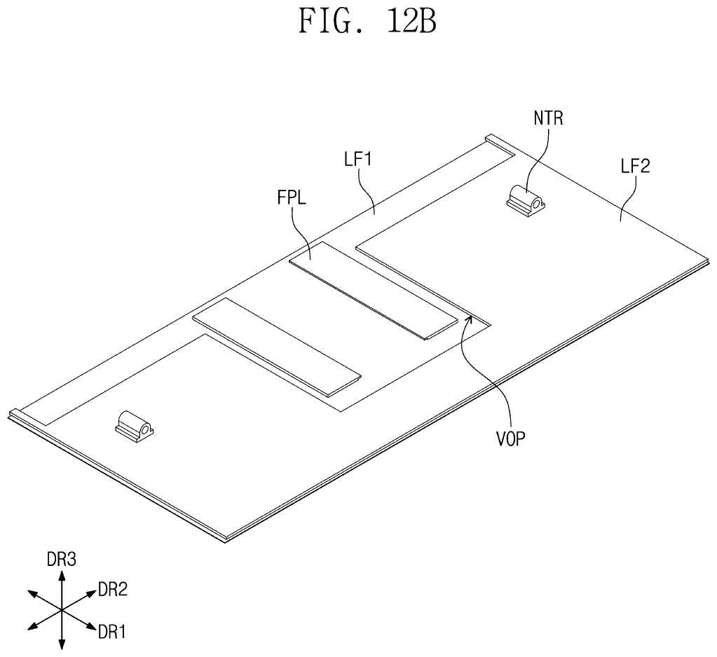

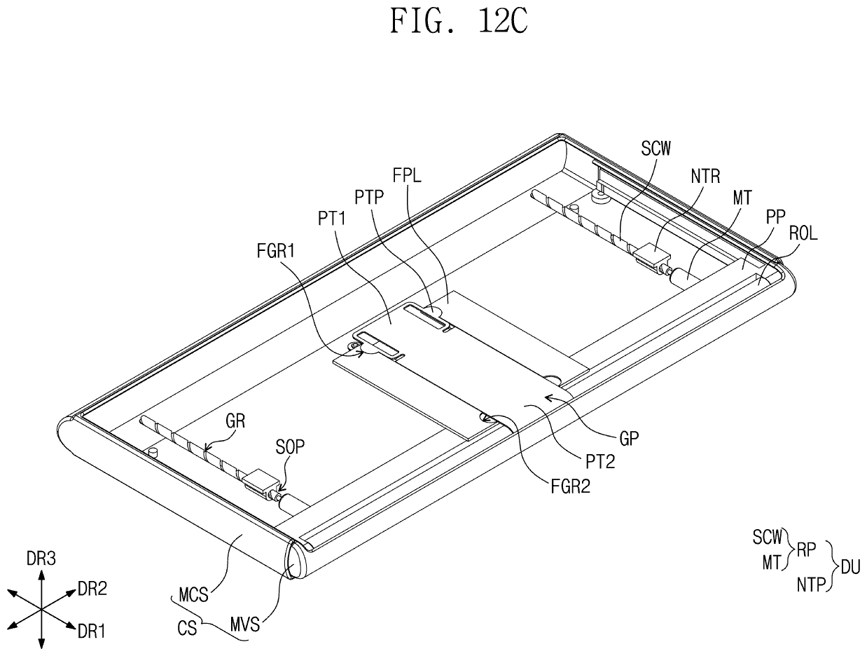

FIG. 12A is a perspective view of a fixing plate illustrated in FIG. 7, according to an embodiment. FIG. 12B is a perspective view illustrating coupling of a first fixed portion and a fixing plate and coupling of a second fixed portion and nut parts, according to an embodiment. FIG. 12C is a perspective view illustrating coupling of a fixing plate and a guide part, according to an embodiment.

Among components illustrated in FIGS. 12A to 12C, description of components which are the same as/similar to the components described with reference to the aforementioned drawings will be omitted or simplified.

In an embodiment and referring to FIGS. 7 and 12A, the fixing plates FPL may be directed parallel to a plane defined by the first direction DR1 and the second direction DR2. The fixing plates FPL may each have long sides extending in the first direction DR1 and short sides extending in the second direction DR2.

In an embodiment, rail grooves RGR may be respectively defined at the one-side portions of the fixing plates FPL that are facing each other in the second direction DR2. The rail grooves RGR may respectively extend toward two sides, which are disposed opposite to each other in the first direction DR1, of the fixing plates FPL.

In an embodiment, fixing grooves FGR may be respectively defined at the one-side portions of the fixing plates FPL that are facing each other. The fixing grooves FGR may extend in the second direction DR2 from the rail grooves RGR. The fixing grooves FGR and the rail grooves RGR may be defined in the second direction DR2. For example, the fixing grooves FGR may each have a shape corresponding to a portion of a circle.

In an embodiment, the fixing grooves FGR may include first fixing grooves FGR1 and second fixing grooves FGR2. A pair of first fixing grooves FGR1 may be spaced apart from a pair of second fixing grooves FGR2 in the first direction DR1. The first fixing grooves FGR 1 may be disposed adjacent to one side of the fixing plate FPL, which is disposed adjacent to the first partition wall BW1, among the two sides of the fixing plate FPL which are disposed opposite to each other in the first direction DR1. The second fixing grooves FGR2 may be disposed adjacent to the other side of the fixing plate FPL among the two sides of the fixing plate FPL which are disposed opposite to each other in the first direction DR1. The first fixing grooves FGR1 and the second fixing grooves FGR2 may be spaced apart from each other in the first direction DR1.

Referring to FIG. 12B, for convenience of explanation, it is illustrated that a rear surface of a first fixed portion LF1, a rear surface of a second fixed portion LF2, and a rear surface of the fixing plate FPL face upwards. In an embodiment, the fixing plates FPL may be disposed on the rear surface of the first fixed portion LF1. When viewed on a plane, the fixing plates FPL may be disposed inside a receiving opening VOP (see FIG. 6A) defined in the second fixed portion LF2.

In an embodiment, when viewed on a plane, the fixing plate FPL may be disposed on the rear surface of the first fixed portion LF1 which is exposed to the outside from the second fixed portion LF2 by the receiving opening VOP. An upper surface of the fixing plate FPL may be attached to the rear surface of the first fixed portion LF1. Accordingly, locations of the fixing plates FPL may be fixed regardless of whether the display device DD (see FIG. 1A and FIG. 1B) is in an unfolded state or in an inserted state.

In an embodiment, the nut parts NTR may be disposed on the rear surface of the second fixed portion LF2. The nut parts NTR may be fixed on the rear surface of the second fixed portion LF2. Accordingly, locations of the nut parts NTR may be fixed regardless of whether the display device DD (see FIG. 1A and FIG. 1B) is in an unfolded state or in an inserted state.

Referring to FIG. 12C, for convenience of explanation, the first fixed portion LF1 and the second fixed portion LF2, in FIG. 12B, are omitted, and only the fixing plates FPL, which are disposed on the rear surface of the first fixed portion LF1, and the nut parts NTR, which are disposed on the rear surface of the second fixed portion LF2, are illustrated. In addition, FIG. 12C illustrates the fixing plates FPL and the guide part GP in an inserted state.

In an embodiment, when the first and second fixed portions LF1 and LF2 in FIG. 12B are disposed on the guide part GP, the fixing plates FPL may be coupled to the guide part GP. Protrusion portions PTP may be disposed in the first fixing grooves FGR1. Accordingly, a gap between the fixing plates FPL and the guide part GP may not occur in an inserted state of the display device DD (see FIG. 1A).

In an embodiment, the nut parts NTR may be coupled to the screw parts SCW, where the screw parts SCW may be inserted into the openings SOP defined in the nut parts NTR. Although not illustrated, the spiral grooves GR, which are defined on the outer surfaces of the screw parts SCW, may interlock with the protrusion portions, which are disposed inside the openings SOP.

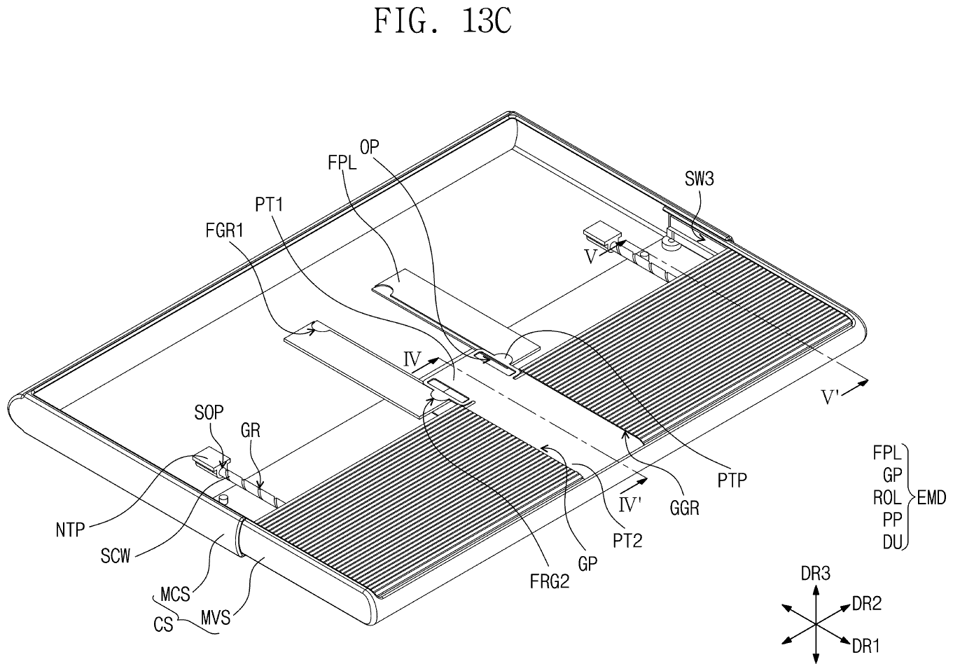

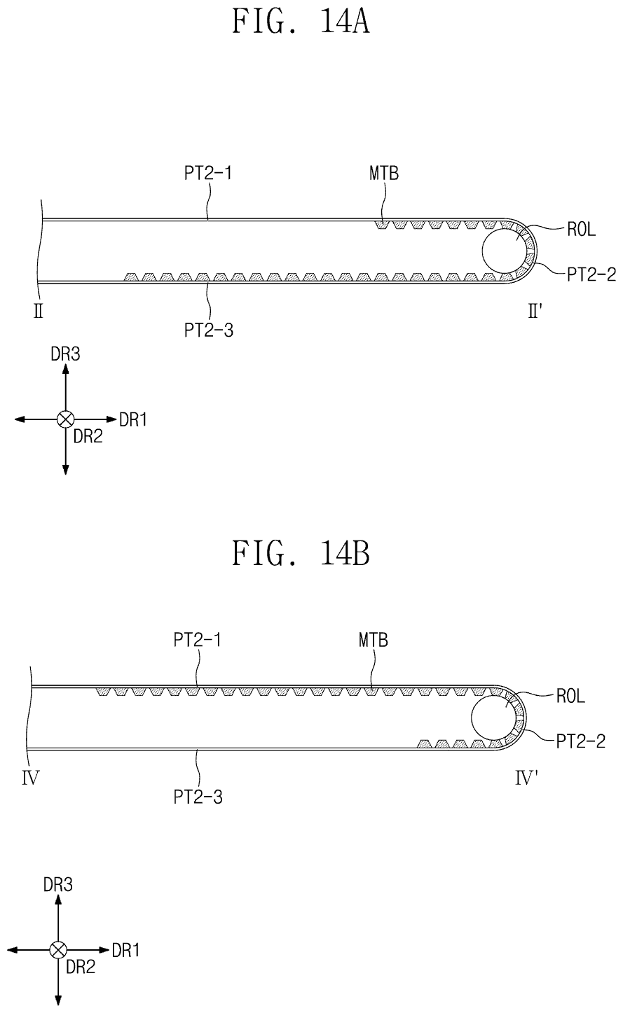

FIGS. 13A to 13C are perspective views illustrating movement of support bars, according to an embodiment. FIG. 14A is a cross-sectional view taken along line II-II′ in FIG. 13A, according to an embodiment. FIG. 14B is a cross-sectional view taken along line III-III′ in FIG. 13C, according to an embodiment.

In an embodiment and by way of example, FIGS. 13A and 14A illustrate an extension module EMD, a case CS, and support bars MTB in an inserted state, and FIGS. 13C and 14B illustrate an extension module EMD, a case CS, and support bars MTB in an unfolded state.

For convenience of explanation, a display module DM, an upper plate UTP, a second fixed portion LF2, and some of the support bars MTB may be omitted in FIGS. 13A to 14B. In addition, components other than the support bars MTB, a guide part GP, and a roller ROL are omitted in FIGS. 14A and 14B.

Among components illustrated in FIGS. 13A to 14B, description of components which are the same as/similar to the components described with reference to the aforementioned drawings will be omitted or simplified.

In an embodiment and referring to FIGS. 13A and 14A, the support bars MTB may be connected to the guide part GP and a moving case MVS. The guide part GP may be disposed in guide grooves GGR. Some support bars MTB among the support bars may be disposed on a rear surface of a (2-1)-th part PT2-1. Other support bars MTB may be arranged in a curved shape between a rear surface of a (2-2)-th part PT2-2 and an outer surface of the roller ROL. The rest support bars MTB may be disposed on an upper surface of a (2-3)-th part PT2-3 facing the rear surface of the (2-1)-th part PT2-1.

In an embodiment, when the extension module EMD is in an inserted state, the number of the support bars MTB disposed on the upper surface of the (2-3)-th part PT2-3 may be greater than the number of the support bars MTB disposed on the rear surface of the (2-1)-th part PT2-1.

In an embodiment and referring to FIG. 13B, motor parts MT may rotate about a rotation axis that is parallel to a first direction DR1. When the motor parts MT rotate, screw parts SCW connected to the motor parts MT may rotate about the rotation axis that is directed parallel to the first direction DR1. When the screw parts SCW rotate, spiral grooves GR and protrusion portions (not illustrated) disposed inside nut parts NTR may interlock with each other. Accordingly, the screw parts SCW and the motor parts MT may move in the first direction DR1 with respect to the nut parts NTR.

In an embodiment, when the screw parts SCW and the motor parts MT move in the first direction DR1, the pressurizing part PP, in FIG. 11, which is connected to the motor parts MT may move in the first direction DR1. The roller ROL connected to the pressurizing part PP may move in the first direction DR1.

In an embodiment, when the pressurizing part PP and the roller ROL move in the first direction DR1, the moving case MVS connected to the pressurizing part PP, the guide part GP connected to the moving case MVS, and the support bars MTB disposed between the guide part GP and the roller ROL may move in the first direction DR1.

In an embodiment, since the moving case MVS moves in the first direction DR1, the case CS may extend in the first direction DR1. An overlap area of the moving case MVS and a main case MCS may be reduced.

In an embodiment, when the guide part GP coupled to the moving case MVS moves in the first direction DR1, two sides of the (2-1)-th part PT2-1 and protrusion portions PTP, which are disposed opposite to each other in a second direction DR2, may move in the first direction DR1 along the rail grooves RGR in FIG. 12A.

In an embodiment, since openings OP are defined in a first part PT1, the rigidity of the first part PT1 may be reduced and two sides of the first part PT1 which are disposed opposite to each other in the second direction DR2 may be bendable. Accordingly, spacing between the protrusion portions PTP in the second direction DR2 may be reduced, and the protrusion portions PTP may be separated from first fixing grooves FGR1 and disposed in the rail grooves RGR

In an embodiment, the support bars MTB disposed on the upper surface of the (2-3)-th part PT2-3 in FIG. 14A may move along the upper surface of the (2-3)-th part PT2-3 according to the movement of the guide part GP and the roller ROL. The support bars MTB disposed on the rear surface of the (2-2)-th part PT2-2 and the outer surface of the roller ROL may move to an upper part of the pressurizing part PP (see FIG. 14A) along the rear surface of the (2-2)-th part PT2-2 and the outer surface of the roller ROL. The support bars MTB, which have been moved to the upper part, may move along the rear surface of the (2-1)-th part PT2-1. The number of the support bars MTB disposed in the upper part of the pressurizing part PP may increase.

In an embodiment, since centers of the support bars MTB move along the rear surface of the (2-1)-th part PT2-1, the rear surface of the (2-2)-th part PT2-2, and the upper surface of the (2-3)-th part PT2-3, the centers of the support bars MTB may not be bent. Accordingly, wrinkles may not occur in a portion of the display module DM (see FIG. 3) overlapping the centers of the support bars MTB. Thus, the surface quality of the display device DD (see FIG. 1A) may be improved.

In an embodiment and referring to FIGS. 13C and 14B, when the extension module EMD is in an unfolded state, the case CS may extend to the maximum. An overlap area of the moving case MVS and the main case MCS may be a minimum area.

In an embodiment, when the extension module EMD is in the unfolded state, the protrusion portions PTP of the guide part GP may be disposed inside the second fixing grooves FGR2. Accordingly, when the display device DD (see FIG. 1B) is in an extended state, a gap between the guide part GP and the fixing plate FPL may not occur.

In an embodiment, when the extension module EMD is in the unfolded state, the number of the support bars MTB disposed in the upper part of the pressurizing part PP may increase. The number of the support bars MTB disposed on the rear surface of the (2-1)-th part PT2-1 may be greater than the number of the support bars MTB disposed on the upper surface of the (2-3)-th part PT2-3.

Although not illustrated, since the number of the support bars MTB disposed in the upper part of the pressurizing part PP increases, an area of the upper plate UTP and an area of the display module DM, which are exposed to the outside from the case CS, may increase.

Hereinafter, a process in which the display device DD (see FIG. 1B) is changed from the unfolded state to the inserted state will be omitted since the process proceeds in reverse order of the process described with reference to FIGS. 13A to 13C.

FIG. 15A is a cross-sectional view taken along line III-III′ in FIG. 13A, according to an embodiment. FIG. 15B is a cross-sectional view taken along line IV-IV′ in FIG. 13C, according to an embodiment.

Among components illustrated in FIGS. 15A and 15B, description of components which are the same as/similar to the components described with reference to the aforementioned drawings will be omitted or simplified.

In an embodiment and referring to FIGS. 13A and 15A, two sides, which are disposed opposite to each other in the second direction DR2, of the support bars MTB may be coupled to the third sidewall parts SW3. The two sides, which are disposed opposite to each other in the second direction DR2, of the support bars MTB may be coupled to the sliding grooves SWR. Hereinafter, for convenience of explanation, one third-sidewall-part SW3 among the third sidewall parts SW3 will be described.

In an embodiment, when the extension module EMD is in an inserted state, the number of the support bars MTB disposed in the first sliding groove SWR1 may be smaller than the number of the support bars MTB disposed in the second sliding groove SWR2. The support bars MTB disposed in the third sliding groove SWR3 may be disposed on the outer surface of the roller ROL.

In an embodiment and referring to FIGS. 13C, 15A, and 15B, when the extension module EMD is changed from the inserted state to the unfolded state, the support bars MTB may move along the second sliding groove SWR2, pass the third sliding groove SWR3, and move toward the first sliding groove SWR1. The support bars MTB may move along the outer surface of the roller ROL toward the first sliding groove SWR1. The number of the support bars MTB disposed in the first sliding groove SWR1 may increase. The number of the support bars MTB disposed in the first sliding groove SWR1 may be smaller than the number of the support bars MTB disposed in the second sliding groove SWR2.

Accordingly, in an embodiment, an area of the display module DM (see FIG. 1B) exposed to the outside from the case CS (see FIG. 1B) will be increased.

According to an embodiment, centers of a plurality of support bars may move along a guide part. Accordingly, the centers of the support bars may not be deformed, and wrinkles may be prevented from occurring in a display module disposed on the support bars. Therefore, the surface quality of a display device may be improved.

In the above, description has been made with reference to preferred embodiments of the invention, but those skilled in the art or those of ordinary skill in the relevant technical field may understand that various modifications and changes may be made to the invention within the scope while not departing from the spirit and the technology scope of the invention. In addition, embodiments disclosed are not intended to limit the technical spirit of the invention, and all technical ideas disclosed herein should be construed as being included in the scope of the invention. Moreover, embodiments or parts of the embodiments may be combined in whole or in part without departing from the scope of the invention.

What is claimed is:

1. A display device comprising:
a display module including a first region, and a second region which extends from the first region in a first direction, a portion of which is folded to be disposed under the first region;
an extension module disposed between the first region and the portion of the second region disposed under the first region; and
a plurality of support bars disposed on a rear surface of the second region,
wherein the extension module includes
a plurality of fixing plates disposed under the first region, and
a guide part having a first part, at least a portion of which is disposed between the plurality of fixing plates under the first region, and a second part, at least a portion of which is disposed between the rear surface of the second region and upper surfaces of the plurality of support bars,
wherein centers of the plurality of support bars overlap the second part.

2. The display device of claim 1, wherein a plurality of rail grooves are defined at sides of the plurality of fixing plates to be facing each other in a second direction crossing the first direction, wherein
the first part moves along the plurality of rail grooves in the first direction.

3. The display device of claim 2, wherein the first part comprises,
a moving portion having a flat surface defined by the first direction and the second direction; and
a plurality of protrusion portions extending in the second direction from two sides of the moving portion which are disposed opposite to each other in the second direction,
a plurality of fixing grooves defined in the plurality of fixing plates to extend from the plurality of rail grooves in the second direction, wherein
the plurality of protrusion portions are disposed in the plurality of fixing grooves when the extension module is in an unfolded state in which the extension module extends in the first direction or in an inserted state in which the extension module shrinks in the first direction.

4. The display device of claim 3, wherein a plurality of openings are defined in the moving portion to be disposed adjacent to the plurality of protrusion portions.

5. The display device of claim 1, wherein a plurality of guide grooves are defined in upper surfaces of the plurality of support bars to face a rear surface of the second part, wherein the second part is disposed inside the plurality of guide grooves.

6. The display device of claim 1, wherein the second part comprises,
a (2-1)-th part disposed on a same flat surface as the first part;
a (2-2)-th part extending from the (2-1)-th part, and having a curved shape; and
a (2-3)-th part disposed under the (2-1)-th part.

7. The display device of claim 6, further comprising:
a main case configured to accommodate the display module and the extension module; and
a moving case which moves in the first direction with respect to the main case,
wherein the moving case includes,
a bottom part defined by the first direction and a second direction crossing the first direction, and
a plurality of sidewall parts disposed at two sides of the bottom part which are disposed opposite to each other in the second direction.

8. The display device of claim 7, wherein a plurality of sliding grooves, at least a portion of each of which has a curved shape, are defined in inner surfaces of the plurality of sidewall parts to face each other, wherein
two sides of the plurality of support bars disposed opposite to each other in the second direction are disposed inside the plurality of sliding grooves.

9. The display device of claim 7, wherein the guide part further comprises a third part extending from the (2-3)-th part in the first direction,
wherein the third part is coupled to the bottom part.

10. The display device of claim 1, further comprising an upper plate disposed between the first region and the first part,
wherein the fixing plate is disposed on a lower surface of the upper plate.

11. A display device comprising:
a display module including a first region, and a second region which extends from the first region in a first direction, a portion of which is folded to be disposed under the first region;
an extension module disposed between the first region and the portion of the second region disposed under the first region; and
a plurality of support bars, at least some of which are disposed under the second region, and in which a plurality of guide grooves are defined in upper surfaces of the plurality of support bars to face a rear surface of the second region,
wherein the extension module includes
a guide part which is disposed in the guide groove, at least a portion of which has a curved shape, and
a plurality of fixing plates disposed at two sides of the guide part which are disposed opposite to each other in a second direction crossing the first direction, and which are disposed under the first region, wherein
the plurality of support bars move along the guide part.

12. The display device of claim 11, wherein a plurality of rail grooves extending in the first direction are defined at sides of the plurality of fixing plates to be facing each other,
wherein when the guide part moves along the plurality of rail grooves, the plurality of support bars move along the curved shape.

13. The display device of claim 12, wherein the guide part comprises,
a first part which is disposed under the first region, and which includes a moving portion disposed between the plurality of fixing plates and a plurality of protrusion portions extending from the moving portion in the second direction, and
a second part which is disposed under the second region and which extends from the first part in the first direction, at least a portion of which has the curved shape.

14. The display device of claim 13, wherein a first groove is defined adjacent to one side of the fixing plate in the first direction to extend from the plurality of rail grooves in the second direction,
a second groove is defined adjacent to the other side of the fixing plate in the first direction to extend from the plurality of rail grooves in the second direction,
wherein when the plurality of protrusion portions move from the first groove to the second groove, the extension module extends in the first direction.

15. The display device of claim 14, wherein a plurality of openings are defined at two sides of the first part to be disposed opposite to each other in the second direction.

16. The display device of claim 13, further comprising,
a main case which accommodates the display module and the extension module; and
a moving case which moves in the first direction with respect to the main case,
wherein the moving case includes a bottom part, and a plurality of sidewall parts extending in a third direction crossing a plane defined by the first direction and the second direction from two sides of the bottom part which are disposed opposite to each other in the second direction.

17. The display device of claim 16, wherein a plurality of sliding grooves, at least portion of which has a curved shape, are defined in inner surfaces of the plurality of sidewall parts to face each other, and
wherein two sides of the plurality of support bars which are disposed opposite to each other in the second direction are disposed inside the plurality of sliding grooves.

18. The display device of claim 17, wherein the guide part further comprises a third part extending from the second part in the first direction to be disposed under the first part,
wherein the third part is coupled to the bottom part.

19. The display device of claim 16, wherein the extension module further comprises,
a pressurizing part disposed between the plurality of sidewall parts;
a drive part coupled to one side of the pressurizing part, which is defined as a side facing the main case, among two sides of the pressurizing part that are disposed opposite to each other in the first direction; and
a roller coupled to an other side of the pressurizing part.

20. The display device of claim 11, wherein the plurality of guide grooves are defined in a center of each of the plurality of support bars.
